(19) United States
(12) Patent Application Publication
(10) Pub. No.: US 2009/0057784 A1
(43) Pub. Date: Mar. 5, 2009

(54) Extension tailored device

(75) Inventor: Yuan-Feng Chen, Hsinchu City (TW)

Correspondence Address: BIRCH STEWART KOLASCH & BIRCH, PO BOX 747, FALLS CHURCH, VA, 22040-0747, US

(73) Assignee: Applied Intellectual Propersties Co., Ltd.

(21) Appl. No.: 11/896,593

(22) Filed: Sep. 4, 2007

(51) Int. Cl. H01L 29/78

(52) U.S. Cl. 257/408; 257/E29.266

(57) ABSTRACT

The present invention discloses a semiconductor device with tailored extension structure comprising a semiconductor substrate. A gate dielectric is formed on the semiconductor substrate. A gate is formed on the gate dielectric. A first isolation layer is formed over the sidewall of the gate. Dielectric spacers are formed on the sidewall of the first isolation layer. And at least one of the p-n junctions of source and drain regions is formed under the dielectric spacers and therefore forming the fringing field induced extension region. Silicide layer is formed on the gate or the doped regions. The first dielectric layer is formed over the silicide layer, dielectric spacer and portion of semiconductor substrate. The second dielectric layer is formed over the first dielectric layer. A metal plug or interconnecting structure is formed in the first dielectric layer and second dielectric layer to electrically connect to at least one of doped regions.

The present invention relates to a semiconductor device, and more specifically, to a field effect transistor with tailored channel extension structure capable of improving gate oxide reliability, reducing parasitic capacitance and adjusting its channel extension current or turn-on resistance.

### BACKGROUND OF THE INVENTION

The semiconductor industry has been advanced to the field of Ultra Large Scale Integrated Circuit (ULSI) technologies. The fabrication of the metal-oxide-semiconductor field effect transistors (MOSFETs) and related memories also follows the trend of the reduction in the devices' physical dimensions. However, as these devices scaling down into deep submicron size, their gate oxide thickness and source/drain junction depth are also required to shrink. As a result, short channel effect, hot carrier effect and gate oxide leakage are often found in these rapidly scaled devices. The MOSFETs include various types of devices such as high performance logic MOSFETs, low power logic MOSFETs, high voltage MOSFETs, power MOSFETs, RF MOSFETs and non-volatile memories. Different types of devices have been developed for specific applications' requirements in each of these segments. Important device structures including lightly doped drain (LDD) MOSFETs and double doped drain (DDD) MOSFETs are developed to resolve some of their concerns. For the requirement of high speed turn-on and low turn-off leakage, the source/drain (S/D) extension resistance in LDD and gate to S/D parasitic capacitance are improved by adjusting the devices' doping processes. However, the doping concentration and profile are bound to the physical limitation of dopants' solid solubility and thermal diffusion.

FIG. 1 illustrates typical failure mechanisms including “localized gate oxide leakage” and “high parasitic gate-to-source capacitance” found in modern scaled MOSFET devices' applications. For a typical n-channel MOSFET, these mechanisms are seen in a high drain voltage, Vd, and high gate voltage, Vg, in its turn-on operation while the source voltage, Vs, and body voltage, Vb, are in a low voltage or grounded. As Vg is increased and applied to the gate, the gate oxide leakage will take place in a local portion of the thin gate oxide between the gate and source extension where a high electrical field is induced by the potential drop between Vg and Vs.

As also shown in FIG. 1, the total parasitic gate-to-source capacitance is proximately equal to the gate to source extension overlapped capacitance plus fringing capacitors near the source side with source extension. The total gate-to-source coupling capacitance is highly related to the gate oxide thickness and source extension position. A RC delay time is needed for Vg to approach the transistor's threshold voltage before the channel has been turned on during its gate charging stage. Therefore, the devices in the prior art have found large gate-to-source coupling capacitance as well as gate oxide degradation problems due to their high gate to source coupling capacitance and electrical field. A device having low coupling capacitance and induced field is needed to prevent local gate oxide degradation and gate charging delay.

The development of MOSFETs progresses toward the trends of low gate leakage and fast turn-on switch because these requirements are necessary for the application of high speed and low power system. The MOSFET needs to turn on the channel in a short period of time. Therefore, the thin gate dielectric that is used under the gate requires high quality in insulation and good durability in voltage switching. At present, the gate dielectric used in submicron MOSFETs is approaching only few nanometers. As known in the art, the gate oxide integrity is the key challenge in MOSFET scaling. In order to attain better controllability of MOSFETs' channels, the thickness of the gate dielectric under the gate has to be scaled down. Furthermore, the channel hot carrier effect has severely degraded those conventional submicron devices. Therefore, modern devices' channel and source/drain doping profiles need to be improved to suppress the hot carrier effects for long term reliability.

In the prior art, please refer to the article written by Hiroaki Mikoshiba et al, entitled “Comparison of Drain Structures in n-Channel MOSFETs”, IEEE Transaction on Electron Devices, vol. ED-33. No. 1, pp. 140, January 1986. The other device structure may be referred to article written by T. Y. Huang et al, entitled “A Novel Submicron LDD Transistor with Inverse-T Gate Structure”, International Electron Devices Meeting (IEDM), pp. 742, 1986. The paper disclosed a MOSFET with inverse-T structure and double doped drain.

### SUMMARY OF THE INVENTION

The object of the present invention is to disclose a semiconductor device capable of improving gate oxide reliability, reducing parasitic capacitance and adjusting its channel extension current or turn-on resistance.

The present invention discloses a semiconductor device, and more specifically, to a field effect transistor with tailored channel extension structure comprising a semiconductor substrate. A gate oxide is formed on the semiconductor substrate. A gate structure is formed on the gate oxide. An isolation layer is formed on the sidewall of the gate structure. The dielectric spacers are formed on the sidewall of the isolation layer and source and drain regions formed adjacent to the gate structure. And at least one of the p-n junctions of source and drain regions is located under the spacer structure. Salicide or metal-semiconductor compound is formed on at least one of the gate structure, source or drain regions. An anti-punch-through implantation region is optionally formed under said gate oxide.

The semiconductor device with tailored channel extension structure further comprises pocket ion implantation region located adjacent to the source or drain region and under the spacer structure, wherein the conductive type of the pocket ion implantation region is opposite to the one of the source and drain regions. And at least one of the p-n junctions of source and drain regions is located under the spacer structure. Alternatively, the semiconductor device with tailored channel extension structure further includes lightly doped drain region adjacent to the source or drain region, wherein the junction of the lightly doped drain region is under the spacer structure and shallower than the one of the source and drain regions and the lightly doped drain region is closer to the channel under the gate structure than the source and drain regions; and pocket ion implantation region adjacent to the source or drain region, wherein the conductive type of the pocket ion implantation region is opposite to the one of the source and drain regions. And at least one of the p-n junctions of lightly doped drain regions is located under the spacer structure. Further embodiment, the semiconductor device with tailored channel extension structure further comprises double doped drain region adjacent to the source or drain region, wherein the junction of the double doped drain region is under the spacer structure and deeper than the one of the source and drain regions and the double doped drain region is closer to the channel under the gate structure than the source and drain regions; and pocket ion implantation region adjacent to the double doped drain region, wherein the conductive type of the pocket ion implantation region is opposite to the one of the source and drain regions. And at least one of the p-n junctions of double doped drain regions is located under the spacer structure.

The dielectric spacer includes oxide or nitride or oxynitride or the material having charge trapping density higher than 10⁻¹⁵/cm³ or the combined multiple layers thereof. The present invention may further include first dielectric layer attached on the first spacers, wherein the first dielectric layer is formed of oxide, nitride or oxynitride or the material having energy gap greater than 4 eV or the combination thereof. The isolation layer is formed of oxide or the material having energy gap larger than 6 eV. Wherein the silicide material includes TiSi₂, WSi₂, CoSi₂ or NiSi.

The present invention further discloses a semiconductor device with tailored channel extension structure comprising a semiconductor substrate and a gate oxide formed on the semiconductor substrate. A gate structure is formed on the gate oxide. A first isolation layer is formed over the sidewall of the gate structure. Dielectric spacers are formed on the sidewall of the first isolation layer and source and drain regions formed adjacent to the gate structure. And at least one of the p-n junctions of source and drain regions is located under the spacer structure. Salicide or metal-semiconductor compound is formed on at least one of the gate structure, source or drain regions. A first dielectric layer is formed over portions of said gate or source or drain regions or metal-semiconductor-compound layer or spacer structure or semiconductor substrate. A second dielectric layer is formed over said first dielectric layer. And a metal plug or interconnection is formed in said first dielectric layer and second dielectric layer wherein said metal plug or interconnection is electrically connected to at least one of source and drain regions.

The present invention further comprises pocket ion implantation region located adjacent to the source or drain region and under the spacer structure, wherein the conductive type of the pocket ion implantation region is opposite to the one of the source and drain regions. Alternatively, the semiconductor device with tailored channel extension structure further comprises lightly doped drain region adjacent to the source or drain region, wherein the junction of the lightly doped drain region is under the spacer structure and shallower than the one of the source and drain regions and the light doped drain region is closer to the channel under the gate structure than the source and drain region; and pocket ion implantation region adjacent to the source or drain region, wherein the conductive type of the pocket ion implantation region is opposite to the one of the source and drain region. In another preferred embodiment, the present invention further comprises double doped drain region adjacent to the source or drain region, wherein the junction of the double doped drain region is under the spacer structure and deeper than the one of the source and drain regions and the double doped drain region is closer to the channel under the gate structure than the source and drain regions; and pocket ion implantation region adjacent to the double doped drain region and under the spacer structure, wherein the conductive type of the pocket ion implantation region is opposite to the one of the source and drain regions.

The dielectric spacer includes oxide or nitride or oxynitride or the material having charge trapping density higher than 10⁻¹⁵/cm³ or the combined multiple layers thereof. The semiconductor device with tailored channel extension structure may further comprise first dielectric layer attached on the dielectric spacers, wherein the first dielectric layer are formed of oxide, nitride or oxynitride or the material having energy gap greater than 4 eV or the combination thereof. The second dielectric layer later is formed of oxide or the material having energy gap larger than 7 eV. The silicide material includes TiSi₂, CoSi₂ or NiSi.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a cross sectional view of a semiconductor device illustrating the prior art and its related problems.

FIG. 2 is a cross sectional view of a semiconductor wafer illustrating the first embodiment having electrical fringing field according to the present invention.

FIG. 3 is a cross sectional view of a semiconductor wafer illustrating the second embodiment having gate-to-source parasitic fringing capacitance according to the present invention.

FIG. 4 is a cross sectional view of a semiconductor wafer illustrating the third embodiment having charge-induced field-effect extension according to the present invention.

FIG. 5 is a cross sectional view of a semiconductor wafer illustrating the forth embodiment according to the present invention.

FIG. 6 is a cross sectional view of a semiconductor wafer illustrating the fifth embodiment according to the present invention.

FIG. 7 is a cross sectional view of a semiconductor wafer illustrating the sixth embodiment according to the present invention.

FIG. 8 is a cross sectional view of a semiconductor wafer illustrating the seventh embodiment according to the present invention.

FIG. 9 is a cross sectional view of a semiconductor wafer illustrating the eighth embodiment according to the present invention.

FIG. 10 is a cross sectional view of a semiconductor wafer illustrating the ninth embodiment according to the present invention.

FIG. 11 is a cross sectional view of a semiconductor wafer illustrating the tenth embodiment according to the present invention.

FIG. 12 is a cross sectional view of a semiconductor wafer illustrating the eleventh embodiment according to the present invention.

FIG. 13 is a cross sectional view of a semiconductor wafer illustrating the twelfth embodiment according to the present invention.

FIG. 14 is a cross sectional view of a semiconductor wafer illustrating the thirteenth t embodiment according to the present invention.

FIG. 15 is a cross sectional view of a semiconductor wafer illustrating the fourteenth embodiment according to the present invention.

FIG. 16 is a cross sectional view of a semiconductor wafer illustrating the fifteenth embodiment according to the present invention.

FIG. 17 is a cross sectional view of a semiconductor wafer illustrating the sixteenth embodiment according to the present invention.

FIG. 18 is a cross sectional view of a semiconductor wafer illustrating the seventeenth embodiment according to the present invention.

FIG. 19 is a cross sectional view of a semiconductor wafer illustrating the eighteenth embodiment according to the present invention.

FIG. 20 is a cross sectional view of a semiconductor wafer illustrating the nineteenth embodiment according to the present invention.

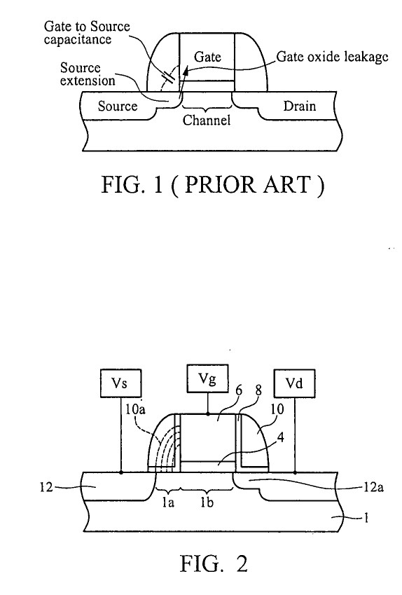

### DETAILED DESCRIPTION OF THE PREFERRED EMBODIMENT

The present invention proposes a novel semiconductor device with tailored channel extension structure. In the device, the channel extension structure capable of improving gate oxide reliability, reducing parasitic capacitance and adjusting its channel extension current or turn-on resistance. The detail description will be seen as follows. A semiconductor substrate or a semiconductor-on-insulator substrate is provided for the present invention. In a preferred embodiment, as shown in the FIG. 2, a single crystal silicon substrate 1 with a <100> or <111> crystallographic orientation is provided. The substrate 1 includes a pattern of active areas. The isolation to separate the devices includes shallow trench isolation (STI) or field oxide (FOX). A thin dielectric layer 4 consisted of silicon dioxide is formed on the substrate 1 to act as gate dielectric. Typically, the layer 4 can be grown in oxygen ambient at a temperature of about 700 to 1100 degrees centigrade. Other method, such as chemical vapor deposition, can also form the oxide. In the embodiment, the thickness of the silicon dioxide layer 4 is approximately 15-250 angstroms. Subsequently, a conductive layer 6 is formed on the layer 4. The conductive layer 6 may be formed of ion implanted polysilicon, in-situ doped polysilicon or epitaxy silicon. For an embodiment, the doped polysilicon layer 6 is doped by phosphorus using a PH₃ source. A photo-resist defined patterning process is used on the conductive layer 6, thereby forming the gate structure on the silicon substrate 1. It has to be noted that the gate structure located at lower portion of the spacer 10 adjacent to the gate 6. Please refer to FIG. 2, an isolation layer 8 is conformally formed on the substrate 1 and the gate structure 6. The material for forming the isolation layer 8 can be oxide (SiO₂) or (HfO₂) or the material with energy gap higher than 6 eV. One suitable method for the oxide layer 8 includes thermal oxidation and deposition by CVD, for example, Low Pressure Chemical Vapor Deposition (LP-CVD), Plasma Enhance Chemical Vapor Deposition (PE-CVD), High Density Plasma Chemical Vapor Deposition (HDP-CVD). Still referring to FIG. 2, an isotropic etching is performed to create sidewall spacers 10 on the sidewall of the isolation layer 8. Reactive ion etching (RIE) or plasma etching is the typical way to achieve the purpose. The dielectric spacers 10 include the combination of oxide and nitride (ON) structure. The material for the dielectric spacer could be nitride or the material with energy gap smaller than 6 eV. In the preferred embodiment, the reaction gases of the step to form silicon nitride layer include, for example, SiH₄, NH₃N₂, N₂O or SiH₂Cl₂, NH₃N₂, N₂O.

Turning to FIG. 2, at least one of lightly doped drain 12a can be formed by using the gate structure 6 and a pre-defined photolithographic resist as mask then performing an ion implantation to dope ions into the substrate 1. Except the channel region 1b under the gate structure 6, the pre-defined photolithographic resist will determine a tailored extension channel region 1a under at least one of spacer 12. After selectively etching isolation layer 8, portions of the gate 6 and substrate 1 are exposed. The rest of p-n junctions 12 can be formed by performing an ion implantation to dope ions into the substrate 1 using the gate structure 6 and sidewall spacers 10 as a mask. The gate structure 6 can be applied with a gate voltage to induce the fringing field 10a through the nitride spacer. The semiconductor device with tailored channel extension structure includes gate voltage induced channel 1b located under the gate structure and fringe field 10a induced channel 1a between two source and drain junctions.

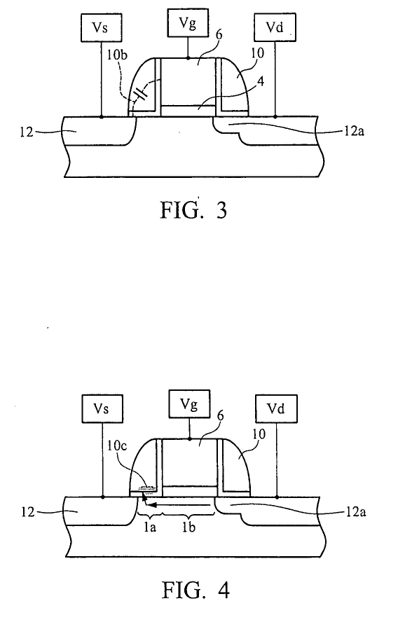

FIG. 3 illustrates the second embodiment of the present invention. The semiconductor device with tailored channel extension structure includes a substrate 1 having one PN junction under the dielectric spacer structure near its source side 12. The parasitic fringing capacitance 10b is formed between the gate and source side. Above the channel is an oxide 4, on top of the oxide layer 4 is a gate 6.

FIG. 4 illustrates the third embodiment of the present invention. The semiconductor device with tailored channel extension structure includes a substrate 1 having one PN junction under the dielectric spacer structure near source side. The gate voltage induced channel is located under the gate structure and between two junctions during operation. Above the channel is an oxide 4, on top of the oxide layer 4 is a gate 6. Spacer 10 is capable of trapping or detrapping charges 10c and is preferably comprised of silicon nitride. The carriers can be injected by forcing an electric current. The carriers 10c can also be trapped or detrapped in the dielectric spacer 10 under the exposure or irradiation of photons, protons, electrons, ions or plasma.

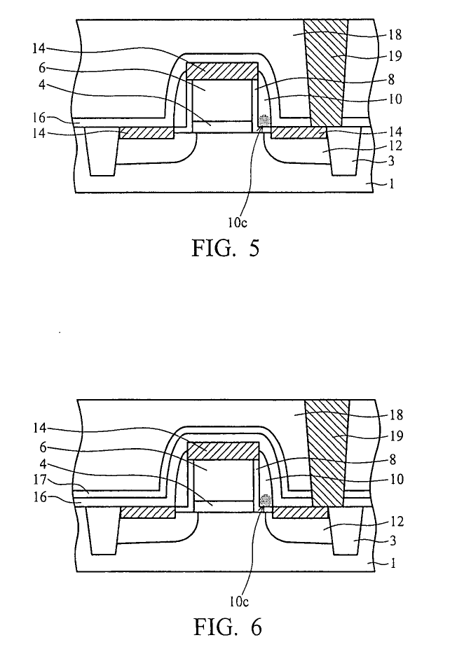

FIG. 5 illustrates the fourth embodiment includes a substrate 1 with STI 3 having one PN junction under the dielectric spacer structure near source side. Silicide or metal-semiconductor compound 14 is introduced on the exposed surface of the top portion of gate and the silicon substrate 1 on the source and drain regions 12 to reduce their resistance. Preferably, the silicide 14 can be TiSi₂, WSi₂, CoSi₂ or NiSi. A first dielectric layer 16 is formed over portions of said gate or source or drain regions or metal-semiconductor-compound layer or spacer trapping structure or semiconductor substrate. A second dielectric layer 18 is formed over said first dielectric layer 16. And a metal plug or interconnection is formed in said first dielectric layer 16 and second dielectric layer 18, wherein said metal plug or interconnection 19 is electrically connected to at least one of the source and drain regions.

FIG. 6 illustrates the fifth embodiment which is similar to the fourth embodiment and further comprises the second isolation layer 17 formed over portions of said gate or source/drain regions or metal-semiconductor-compound layer or spacer structure or semiconductor substrate.

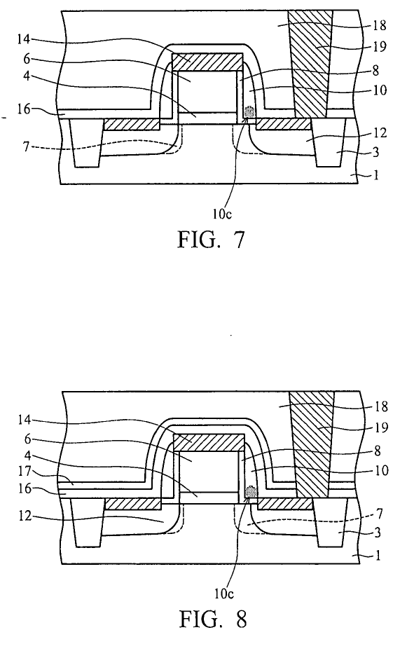

Turning to FIG. 7, the sixth embodiment includes pocket ion implantation region 7 adjacent to the source and drain region 12 and adjacent to the gate structure to reduce the short channel effect and increase the efficiency of the hot carrier injection.

FIG. 8 shows the alterative example as seventh embodiment for the present invention which is similar to the sixth embodiment and further comprises the second isolation layer 17 formed over portions of said gate or source/drain regions or metal-semiconductor-compound layer or spacer structure or semiconductor substrate. It also includes pocket ion implantation region 7 adjacent to the source and drain region 12. The conductive type of the pocket implant region 7 is opposite to the one of the source and drain region 12.

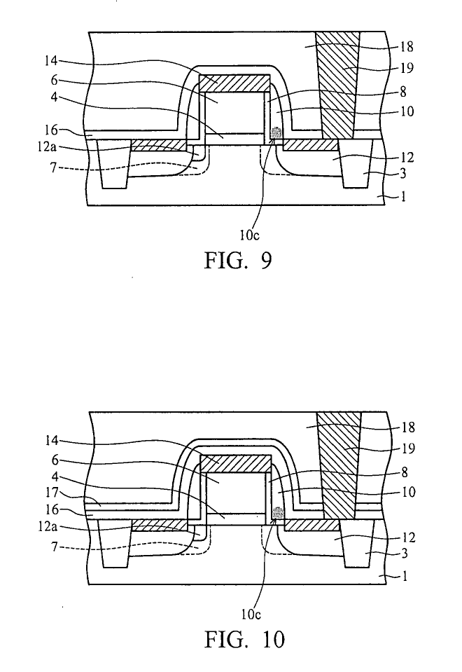

FIGS. 9 and 10 are the alternative approaches with respect to the embodiments similarly shown in FIGS. 7 and 8. The eighth and ninth embodiments introduce the lightly doped drain 12a to control the hot carriers and further comprise pocket ion implant region 7 adjacent to the source and drain region 12 and under the spacers 10. The conductive type of the pocket ion implantation region is opposite to the one of the source and drain region. The junction of the lightly doped drain is shallower than the one of the source and drain region. The lightly doped drain is also closer to the channel under the gate. Compared to the eighth embodiment, the ninth embodiment further comprises the second isolation layer formed over portions of said gate or source/drain regions or metal-semiconductor-compound layer or spacer structure or semiconductor substrate.

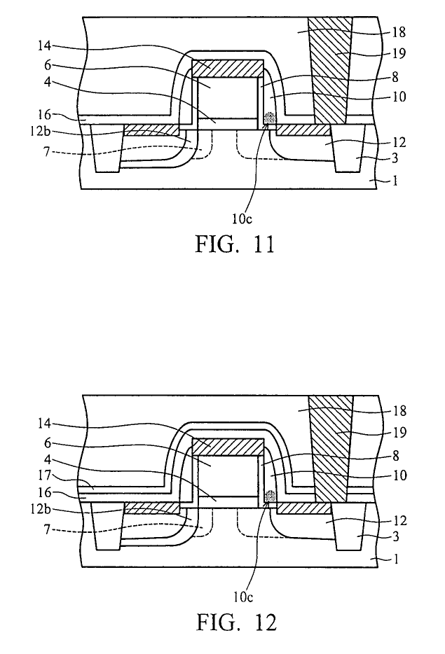

Alternatively, the other embodiments shown in FIGS. 11 and 12 introduce the usage of double diffused drain (DDD) structure 12b to reduce the junction breakdown effect. The conductive ion type of the DDD structure is the same as that of the source and drain region. However, the junctions of double diffused drain (DDD) region 12b are deeper and more lightly than the junctions of the heavily doped source and drain region 12. The embodiments further comprise pocket ion implant region adjacent to the double diffused source and drain region 12b and under the spacer structure 10 of the control gate 6. Compared to the tenth embodiment, the eleventh embodiment further comprises the second isolation layer 17 formed over portions of said gate or source/drain regions or metal-semiconductor-compound layer or spacer structure or semiconductor substrate.

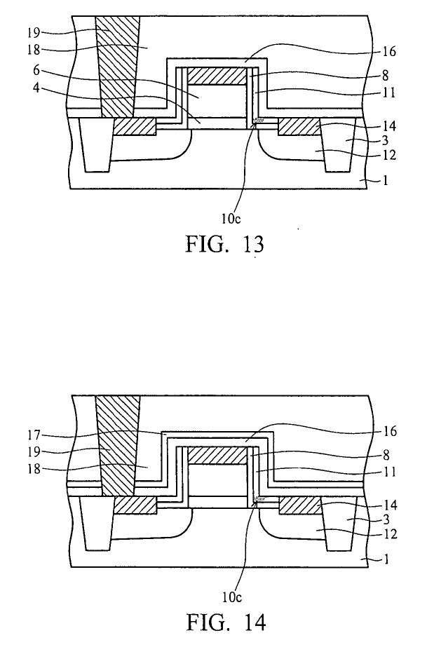

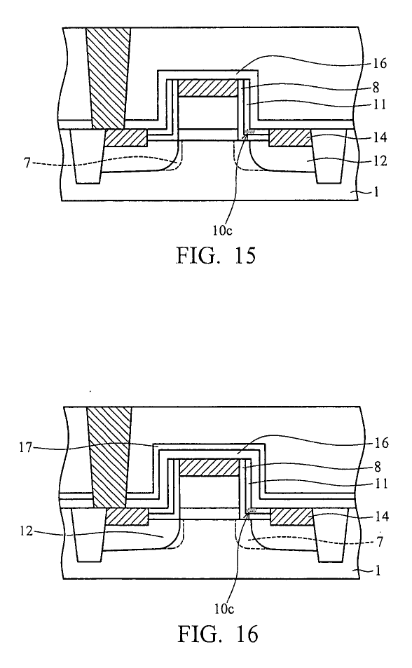

Please refer to FIG. 13, the example is similar to the fourth embodiment except the spacer 10 is L-shaped and formed of oxide. The first isolation layer 8 is formed of oxide or the material with energy gap greater than 6 eV, and the second isolation layer 11 is formed of nitride or the material with energy gap smaller than 6 eV. Similarly, the preferred embodiments from FIG. 10-16 are the alternative solutions for the corresponding examples from FIG. 2-8. The spacers 10 are formed of oxide and the corresponding structures, features are very similar to those corresponding examples. Therefore, the description is omitted.

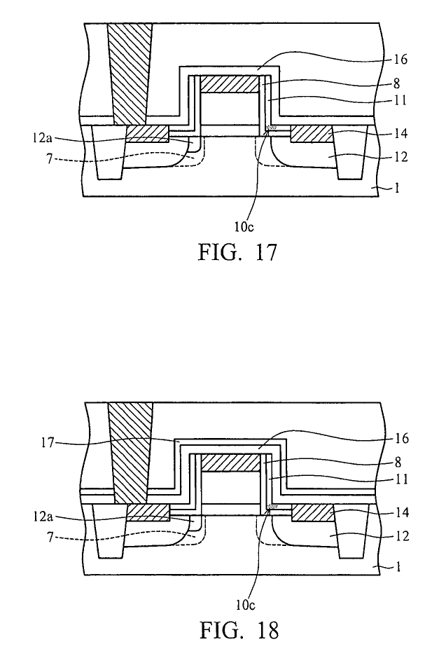

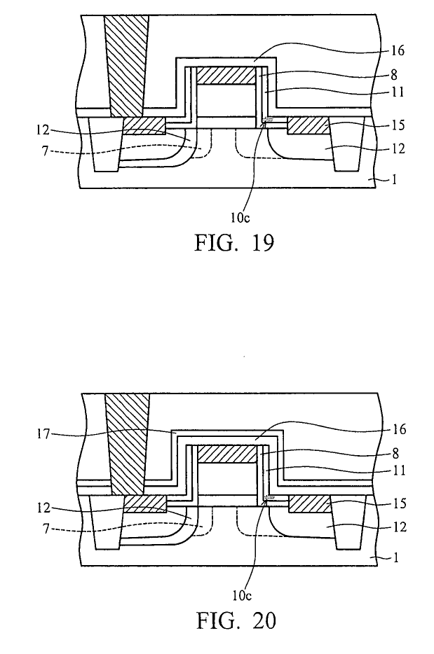

Next, the embodiments shown in FIG. 14-20 are the alternative arrangements that are associated with FIGS. 6-12, correspondingly. The main different is that the L-shaped spacers structure is introduced into the embodiments shown in FIG. 14-20. The L-shaped spacer can be formed of oxide, nitride or the material having energy gap larger than 4 eV.

As will be understood by persons skilled in the art, the foregoing preferred embodiment of the present invention is illustrative of the present invention rather than limiting the present invention. Having described the invention in connection with a preferred embodiment, modification will now suggest itself to those skilled in the art. Thus, the invention is not to be limited to this embodiment, but rather the invention is intended to cover various modifications and similar arrangements included within the spirit and scope of the appended claims, the scope of which should be accorded the broadest interpretation so as to encompass all such modifications and similar structures. While the preferred embodiment of the invention has been illustrated and described, it will be appreciated that various changes can be made therein without departing from the spirit and scope of the invention.

What is claimed is:

1. An extension tailored device comprising:
a semiconductor substrate;
a gate dielectric formed on said semiconductor substrate;
a gate formed on said gate dielectric;
a spacer structure including a first isolation layer formed on the sidewalls of said gate and a dielectric spacer formed on said first isolation layer;
doped regions formed in said semiconductor substrate, wherein at least one of p-n junctions of said doped regions formed under said spacer structure;
a fringing field induced extension region formed adjacent to said extension tailored device's turn-on channel under said gate dielectric and adjacent to at least one of said doped regions whose p-n junction is formed under said spacer structure;
an anti-punch-through implantation region optionally formed under said gate oxide;
a metal-semiconductor-compound layer formed on said gate or said doped regions.

2. The extension tailored device of claim 1, further comprising:
a pocket ion implantation region formed in said semiconductor substrate and located adjacent to at least one of said doped regions, wherein the conductive type of the pocket ion implantation region is opposite to the one of said doped regions.

3. The extension tailored device of claim 1, further comprising:
a lightly doped drain region adjacent to at least one of said doped regions, wherein the p-n junction of said lightly doped drain region formed shallower than the p-n junctions of said doped regions; and said lightly doped drain region is closer to the channel under said gate dielectric than said doped regions; and
a pocket ion implantation region adjacent to at least one of said doped regions or said lightly doped drain region, wherein the conductive type of the pocket ion implantation region is opposite to the one of said doped regions.

4. The extension tailored device of claim 1, further comprising:
a double doped drain region adjacent to at least one of said doped regions, wherein the p-n junction of said double doped drain region is formed deeper than the one of said doped regions; and said double doped drain region is closer to the channel under said gate dielectric than said doped regions and the doping concentration of said double doped drain region is lower than the one of said doped regions; and
a pocket ion implantation region adjacent to at least one of said doped regions or said double doped drain region, wherein the conductive type of the pocket ion implantation region is opposite to the one of the doped regions.

5. The extension tailored device of claim 1, wherein said first isolation layer is formed of oxide or a material having energy gap larger than 6 eV.

6. The extension tailored device of claim 1, wherein said metal-semiconductor-compound layer includes TiSi₂, CoSi₂ or NiSi.

7. The extension tailored device of claim 1, wherein said spacer structure is capable of trapping or detrapping charges thereby altering said extension tailored device's turn-on resistance or the electrical field distribution in said semiconductor substrate or the current flow through said fringing field induced extension region;
and said dielectric spacer is formed of oxynitride or oxide or nitride or a material having charge trapping density higher than 10⁻¹⁵/cm³ or combined multiple layers thereof.

8. The extension tailored device of claim 7, wherein said dielectric spacer is L-shaped; and said spacer structure is capable of trapping or detrapping charges under electrical current injection or exposure of photons, protons, electrons, ions or plasma.

9. The extension tailored device of claim 1 further comprising:
a first dielectric layer formed over portions of said gate or doped regions or metal-semiconductor-compound layer or spacer structure or semiconductor substrate;
a second dielectric layer formed over said first dielectric layer; and
a metal plug or interconnection formed in said first dielectric layer and second dielectric layer, wherein said metal plug or interconnection is electrically connected to at least one of said doped regions.

10. The extension tailored device of claim 9, wherein said first dielectric layer is formed of oxide, nitride or oxynitride or a material having energy gap greater than 4 eV or a combination thereof.

11. The extension tailored device of claim 2, wherein said first isolation layer is formed of oxide or a material having energy gap larger than 6 eV.

12. The extension tailored device of claim 2, wherein said metal-semiconductor-compound layer includes TiSi₂, CoSi₂ or NiSi.

13. The extension tailored device of claim 2, wherein said spacer structure is capable of trapping or detrapping charges thereby altering said extension tailored device's turn-on resistance or the electrical field distribution in said semiconductor substrate or the current flow through said fringing field induced extension region;
and said dielectric spacer is formed of oxynitride or oxide or nitride or a material having charge trapping density higher than 10⁻¹⁵/cm³ or combined multiple layers thereof.

14. The extension tailored device of claim 13, wherein said dielectric spacer is L-shaped; and said spacer structure is capable of trapping or detrapping charges under electrical current injection or exposure of photons, protons, electrons, ions or plasma.

15. The extension tailored device of claim 2 further comprising:
a first dielectric layer formed over portions of said gate or doped regions or metal-semiconductor-compound layer or spacer structure or semiconductor substrate;
a second dielectric layer formed over said first dielectric layer; and
a metal plug or interconnection formed in said first dielectric layer and second dielectric layer, wherein said metal plug or interconnection is electrically connected to at least one of said doped regions.

16. The extension tailored device of claim 15, wherein said first dielectric layer is formed of oxide, nitride or oxynitride or a material having energy gap greater than 4 eV or a combination thereof.

17. The extension tailored device of claim 3, wherein said first isolation layer is formed of oxide or a material having energy gap larger than 6 eV.

18. The extension tailored device of claim 3, wherein said metal-semiconductor-compound layer includes TiSi₂, CoSi₂ or NiSi.

19. The extension tailored device of claim 3, wherein said spacer structure is capable of trapping or detrapping charges thereby altering said extension tailored device's turn-on resistance or the electrical field distribution in said semiconductor substrate or the current flow through said fringing field induced extension region;
and said dielectric spacer is formed of oxynitride or oxide or nitride or a material having charge trapping density higher than 10⁻¹⁵/cm³ or combined multiple layers thereof.

20. The extension tailored device of claim 19, wherein said dielectric spacer is L-shaped; and said spacer structure is capable of trapping or detrapping charges under electrical current injection or exposure of photons, protons, electrons, ions or plasma.

21. The extension tailored device of claim 3 further comprising:
a first dielectric layer formed over portions of said gate or doped regions or metal-semiconductor-compound layer or spacer structure or semiconductor substrate;
a second dielectric layer formed over said first dielectric layer; and
a metal plug or interconnection formed in said first dielectric layer and second dielectric layer, wherein said metal plug or interconnection is electrically connected to at least one of said doped regions.

22. The extension tailored device of claim 21, wherein said first dielectric layer is formed of oxide, nitride or oxynitride or a material having energy gap greater than 4 eV or a combination thereof.

23. The extension tailored device of claim 4, wherein said first isolation layer is formed of oxide or a material having energy gap larger than 6 eV.

24. The extension tailored device of claim 4, wherein said metal-semiconductor-compound layer includes TiSi₂, CoSi₂ or NiSi.

25. The extension tailored device of claim 4, wherein said spacer structure is capable of trapping or detrapping charges thereby altering said extension tailored device's turn-on resistance or the electrical field distribution in said semiconductor substrate or the current flow through said fringing field induced extension region;
and said dielectric spacer is formed of oxynitride or oxide or nitride or a material having charge trapping density higher than 10⁻¹⁵/cm³ or combined multiple layers thereof.

26. The extension tailored device of claim 25, wherein said dielectric spacer is L-shaped; and said spacer structure is capable of trapping or detrapping charges under electrical current injection or exposure of photons, protons, electrons, ions or plasma.

27. The extension tailored device of claim 4 further comprising:
a first dielectric layer formed over portions of said gate or doped regions or metal-semiconductor-compound layer or spacer structure or semiconductor substrate;
a second dielectric layer formed over said first dielectric layer; and
a metal plug or interconnection formed in said first dielectric layer and second dielectric layer, wherein said metal plug or interconnection is electrically connected to at least one of said doped regions.

28. The extension tailored device of claim 27, wherein said first dielectric layer is formed of oxide, nitride or oxynitride or a material having energy gap greater than 4 eV or a combination thereof.

29. An extension tailored device comprising:
a semiconductor substrate;
a gate oxide formed on said semiconductor substrate;
a gate formed 6n said gate oxide;
a spacer structure including a first isolation layer formed on the sidewalls of said gate and a dielectric spacer formed on said first isolation layer;
doped regions formed in said semiconductor substrate, wherein at least one of p-n junctions of said doped regions formed under said spacer structure;
an fringing field induced extension region formed adjacent to said extension tailored device's turn-on channel under said gate dielectric and adjacent to at least one of said doped regions whose p-n junction is formed under said spacer structure;
an anti-punch-through implantation region optionally formed under said gate oxide;
a metal-semiconductor-compound layer formed on said gate and said doped regions;
a second isolation layer formed over portions of said gate or doped regions or metal-semiconductor-compound layer or spacer trapping structure or semiconductor substrate;
a first dielectric layer formed over said second isolation layer;
a second dielectric layer formed over said first dielectric layer; and
a metal plug or interconnection formed in said second isolation layer, first dielectric layer and second dielectric layer, wherein said metal plug or interconnection is electrically connected to at least one of said doped regions.

30. The extension tailored device of claim 29, further comprising:
a pocket ion implantation region formed in said semiconductor substrate and located adjacent to at least one of said doped regions, wherein the conductive type of the pocket ion implantation region is opposite to the one of said doped regions.

31. The extension tailored device of claim 29, further comprising:
a lightly doped drain region adjacent to at least one of said doped regions, wherein the p-n junction of said lightly doped drain region formed shallower than the p-n junctions of said doped regions; and said lightly doped drain region is closer to the channel under said gate dielectric than said doped regions; and
a pocket ion implantation region adjacent to at least one of said doped regions or said lightly doped drain region, wherein the conductive type of the pocket ion implantation region is opposite to the one of said doped regions.

32. The extension tailored device of claim 29, further comprising:
a double doped drain region adjacent to at least one of said doped regions, wherein the p-n junction of said double doped drain region formed deeper than the one of said doped regions; and said double doped drain region is closer to the channel under said gate dielectric than said doped regions and the doping concentration of said double doped drain region is lower than the one of said doped regions; and
a pocket ion implantation region adjacent to at least one of said doped regions or said double doped drain region, wherein the conductive type of the pocket ion implantation region is opposite to the one of the doped regions.

33. The extension tailored device of claim 29, wherein said spacer structure is capable of trapping charges thereby altering said extension tailored device's turn-on resistance or the electrical field distribution in said semiconductor substrate or the current flow through said fringing field induced extension region;
and said dielectric spacer is L-shaped and formed of oxynitride or oxide or nitride or a material having charge trapping density higher than 10⁻¹⁵/cm³ or combined multiple layers thereof.

34. The extension tailored device of claim 30, wherein said spacer structure is capable of trapping charges thereby altering said extension tailored device's turn-on resistance or the electrical field distribution in said semiconductor substrate or the current flow through said fringing field induced extension region;
and said dielectric spacer is L-shaped and formed of oxynitride or oxide or nitride or a material having charge trapping density higher than 10⁻¹⁵/cm³ or combined multiple layers thereof.

35. The extension tailored device of claim 31, wherein said spacer structure is capable of trapping charges thereby altering said extension tailored device's turn-on resistance or the electrical field distribution in said semiconductor substrate or the current flow through said fringing field induced extension region;
and said dielectric spacer is L-shaped and formed of oxynitride or oxide or nitride or a material having charge trapping density higher than 10⁻¹⁵/cm³ or combined multiple layers thereof.

36. The extension tailored device of claim 32, wherein
said spacer structure is capable of trapping charges thereby altering said extension tailored device's turn-on resistance or the electrical field distribution in said semiconductor substrate or the current flow through said fringing field induced extension region;
and said dielectric spacer is L-shaped and formed of oxynitride or oxide or nitride or a material having charge trapping density higher than 10⁻¹⁵/cm³ or combined multiple layers thereof.
